(19) United States
(12) Patent Application Publication
(10) Pub. No.: US 2013/0068603 A1
(43) Pub. Date: Mar. 21, 2013

(54) TOUCH PANEL USING A METAL THIN FILM, AND METHOD FOR MANUFACTURING SAME

(71) Applicant: Min Gi Kwak, Seongnam-si (KR)

(72) Inventor: Min Gi Kwak, Seongnam-si (KR)

(73) Assignee: KOREA ELECTRONICS TECHNOLOGY INSTITUTE, Seongnam-si, Gyeonggi-do (KR)

(21) Appl. No.: 13/699,988

(22) PCT Filed: May 3, 2011
(86) PCT No.: PCT/KR2011/003282

§ 371 Date: Nov. 26, 2012

(30) Foreign Application Priority Data
May 25, 2010 (KR) 10-2010-0048417

(51) Int. Cl. H03K 17/975; H05K 3/00

(52) U.S. Cl. CPC H03K 17/975; H05K 3/00
USPC 200/600; 29/830

(57) ABSTRACT

This invention relates to a touch panel using a metal thin film and a method of manufacturing the same. The touch panel according to an embodiment of the invention includes a transparent substrate; a metal pattern unit formed under the transparent substrate and including at least one first pattern electrode and a first wiring electrode which is connected to the first pattern electrode; and a film substrate combined with the transparent substrate having the metal pattern unit, and including at least one second pattern electrode and a second wiring electrode which is connected to the second pattern electrode, wherein the first pattern electrode is in the form of a mesh of thin wires.

### TECHNICAL FIELD

The present invention relates to a touch panel and a method of manufacturing the same, and more particularly, to a touch panel using a metal thin film and a method of manufacturing the same.

### BACKGROUND ART

A touch panel is an input device which is mounted onto a surface of a display so that physical contact by a finger of a user, etc., is converted into an electrical signal to operate a product, and may be widely applied to a variety of display devices. The demand thereof is drastically increasing these days.

Such a touch panel may be classified into, depending on the operation principle, a resistive type, a capacitive type, a surface acoustic wave (SAW) type, an infrared (IR) type, etc.

A conventional touch panel typically includes a substrate, a metal wiring layer, and a pattern layer. The pattern layer is composed of a plurality of pattern electrodes (touch pattern), and these pattern electrodes generate an electrical signal in response to external physical contact.

As such, the generated electrode signal is transmitted to a controller of a product via metal wires connected to the pattern electrodes, so that the product operates.

However, the conventional touch panel is problematic because surface resistance of a transparent conductive film which is a conductive material that constitutes the pattern electrodes is larger than that of a metal thin film, and thus resistance between the pattern electrodes may increase upon manufacturing a touch panel having a large area and superior performance, and thereby signal sensitivity and detection sensitivity undesirably may decrease somewhat.

Also there is a difference in transmittance, etc., between an area where the pattern electrode is present and an area where the pattern electrode is not present, and thus patterning marks may be undesirably shown in the area where the pattern electrode is present.

Therefore, the development of a touch panel which may decrease resistance between the pattern electrodes to exhibit improved conductivity and detection sensitivity and high transparency is required.

### DISCLOSURE

### Technical Problem

Accordingly, exemplary embodiments of the present invention are intended to provide a touch panel and a method of manufacturing the same, in which resistance between pattern electrodes or between pattern electrodes and wiring electrodes may decrease, thus improving conductivity, detection sensitivity and transparency, and the pattern electrodes and the wiring electrodes may be simultaneously formed thus simplifying the manufacturing process.

### Technical Solution

An aspect of the present invention provides a touch panel, comprising a transparent substrate; a metal pattern unit formed under the transparent substrate and including at least one first pattern electrode and a first wiring electrode which is connected to the first pattern electrode; and a film substrate combined with the transparent substrate having the metal pattern unit, and including at least one second pattern electrode and a second wiring electrode which is connected to the second pattern electrode, wherein the first pattern electrode is in the form of a mesh of thin wires.

Also, the metal pattern unit may be formed using any one selected from among Ag, Al, Cu, Cr and Ni, or an alloy thereof.

Also, the film substrate may comprise ITO (Indium Tin Oxide) or a conductive polymer.

Also, the transparent substrate may be a glass substrate, a transparent silicon substrate or a transparent plastic substrate.

Also, the first pattern electrode may be configured such that the thin wires which are present in an area where the first pattern electrode and the second pattern electrode overlap with each other are disconnected.

Also, the first pattern electrode may be in the form of a mesh of thin wires having a wire width of 1˜10 μm and a spacing of 200 μm or more between the wires.

Another aspect of the present invention provides a method of manufacturing the touch panel, comprising coating any one surface of a transparent substrate with a metal thin film; simultaneously forming at least one first pattern electrode in the form of a mesh of thin wires and a first wiring electrode connected to the first pattern electrode on the metal thin film positioned on the transparent substrate; forming a second pattern electrode on a film substrate, and forming a second wiring electrode which is connected to the second pattern electrode; and combining the transparent substrate and the film substrate.

### Advantageous Effects

According to exemplary embodiments of the present invention, pattern electrodes using a metal thin film can be formed in a mesh shape, so that resistance between pattern electrodes or between pattern electrodes and wiring electrodes can decrease, thus improving conductivity and detection sensitivity of a touch panel.

Also, the formation of pattern electrodes in a mesh shape can increase transparency of a touch panel.

Moreover, pattern electrodes and wiring electrodes can be simultaneously formed, thus simplifying the manufacturing process of a touch panel.

### DESCRIPTION OF DRAWINGS

FIG. 1 is a cross-sectional view illustrating a touch panel according to an embodiment of the present invention;

FIG. 2 is an exploded perspective view of the touch panel of FIG. 1;

FIG. 3 is a front view of the touch panel of FIG. 1; and

FIG. 4 is an enlarged view of the portion A in the touch panel of FIG. 3.

### DESCRIPTION OF THE REFERENCE NUMERALS IN THE DRAWINGS

100: transparent substrate

200: metal pattern unit

220: first pattern electrode

240: first wiring electrode

300: film substrate

320: second pattern electrode

340: second wiring electrode

400: optical transparent adhesive

### MODE FOR INVENTION

Hereinafter, a detailed description will be given of embodiments of the present invention with reference to the appended drawings.

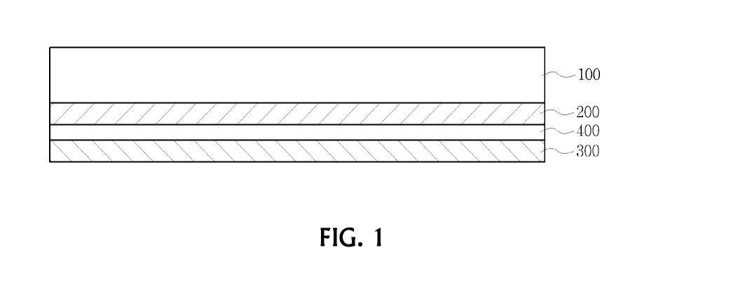

FIG. 1 is a cross-sectional view illustrating a touch panel according to an embodiment of the present invention.

The touch panel according to the embodiment of the present invention includes a transparent substrate 100, a metal pattern unit 200 formed under the transparent substrate 100 and including at least one first pattern electrode 220 and a first wiring electrode 240 which is connected to the first pattern electrode 220, and a film substrate 300 combined with the transparent substrate 100 having the metal pattern unit 200, and including at least one second pattern electrode 320 and a second wiring electrode 340 which is connected to the second pattern electrode 320.

The touch panel according to the embodiment of the present invention is specified below.

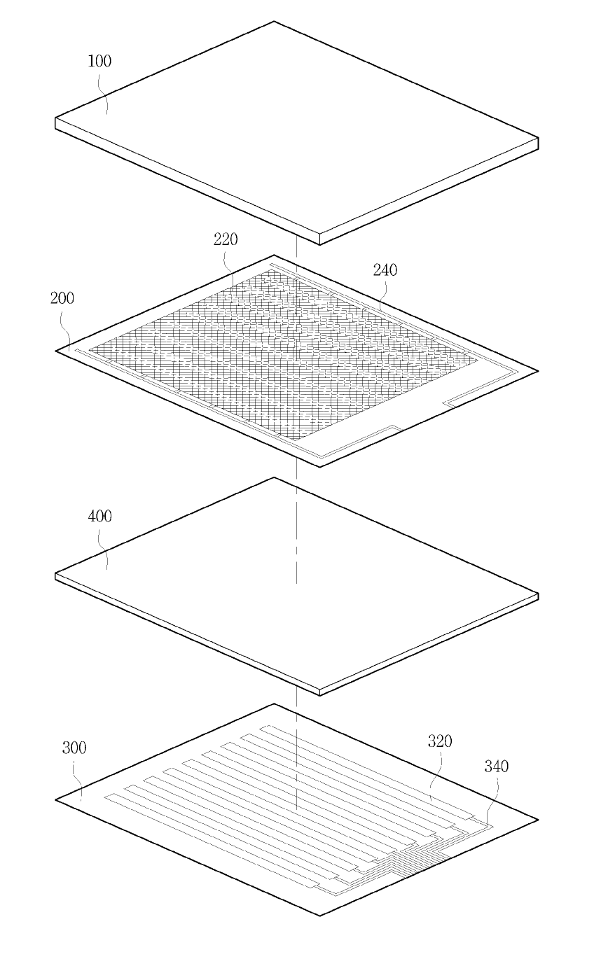

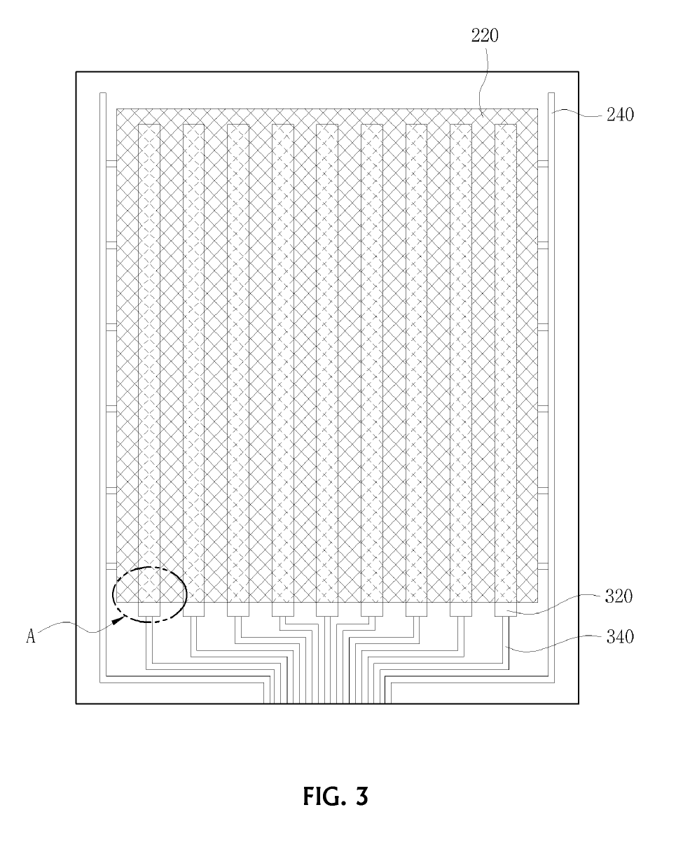

FIG. 2 is an exploded perspective view of the touch panel of FIG. 1, and FIG. 3 is a front view thereof.

With reference to FIGS. 2 and 3, the transparent substrate 100 supports the metal pattern unit 200 and the film substrate 300. The transparent substrate 100 may be a glass substrate composed mainly of SiO₂, but a silicon substrate or a plastic substrate may be utilized. As the transparent substrate 100, any one may be used so long as it supports the metal pattern unit 200 and the film substrate 300.

Particularly in the case where the transparent substrate 100 is a plastic substrate, it is possible to achieve a flexible display thanks to flexibility of the plastic substrate.

The plastic substrate may comprise any one selected from among polycarbonate, polyethyleneterephthalate, polybuthyleneterephthalate, polyphenylene sulfide, polyimide, polyamide imide, polyethersulfone, polyetherimide, and polyetheretherketone. As such, the plastic substrate has to be transparent.

The metal pattern unit 200 is formed under the transparent substrate 100. The metal pattern unit 200 includes at least one first pattern electrode 220 and the first wiring electrode 240 which is connected to the metal pattern unit 220.

The first pattern electrode 220 and the first wiring electrode 240 are electrically connected to each other. The first wiring electrode 240 functions to transmit an electrical signal generated from the first pattern electrode 220 to a controller (not shown) or a flexible printed circuit board (not shown) upon external physical contact by a user.

The controller or the flexible printed circuit board may be connected to the first wiring electrode 240 via an additional connector (not shown).

The metal pattern unit 200 including the first pattern electrode 220 and the first wiring electrode 240 may be formed of any one selected from among Ag, Al, Cu, Cr and Ni, or an alloy thereof.

As the metal pattern unit 200 is made of a metal, resistance between first pattern electrodes 220 included in the metal pattern unit 200 or between the first pattern electrode 220 and the first wiring electrode 240 may decrease. Thereby, conductivity and detection sensitivity of the touch panel may increase.

On the other hand, as the first pattern electrode 220 and the first wiring electrode 240 of the metal pattern unit 200 are made of the same metal material, a process of manufacturing the touch panel may be simplified.

The film substrate 300 may be made of a material for forming a transparent conductive film, such as ITO (Indium Tin Oxide), IZO (Indium Zinc Oxide), ZnO (Zinc Oxide) or In₂O₃ (Indium(III) oxide).

The film substrate 300 includes at least one second pattern electrode 320 and the second wiring electrode 340 which is connected to the second pattern electrode 320. The second pattern electrode 320 is formed by being patterned on the film substrate 300, and the second wiring electrode 340 is formed using an Ag paste.

The second pattern electrode 320 and the second wiring electrode 340 are electrically connected to each other. The second wiring electrode 340 plays a role in transmitting an electrical signal generated from the second pattern electrode 320 to a controller (not shown) or a flexible printed circuit board (not shown) upon external physical contact by a user.

The controller or the flexible printed circuit board may be connected to the second wiring electrode 340 via an additional connector (not shown). The film substrate 300 including the second pattern electrode 320 and the second wiring electrode 340 is combined with the transparent substrate 100 having the metal pattern unit 200.

When the transparent substrate 100 and the film substrate 300 are combined with each other, an optical transparent adhesive 400 may be used. An example of the optical transparent adhesive 400 may include OCA (Optical Clear Adhesive).

In the touch panel according to the embodiment of the present invention, the first pattern electrode 220 may be in the form of a mesh of thin wires.

When the first pattern electrode 220 is in the form of a mesh of thin wires in this way, a conventional phenomenon in which patterning marks are shown in an area where a sensor electrode is present may decrease, thus increasing transparency of the touch panel.

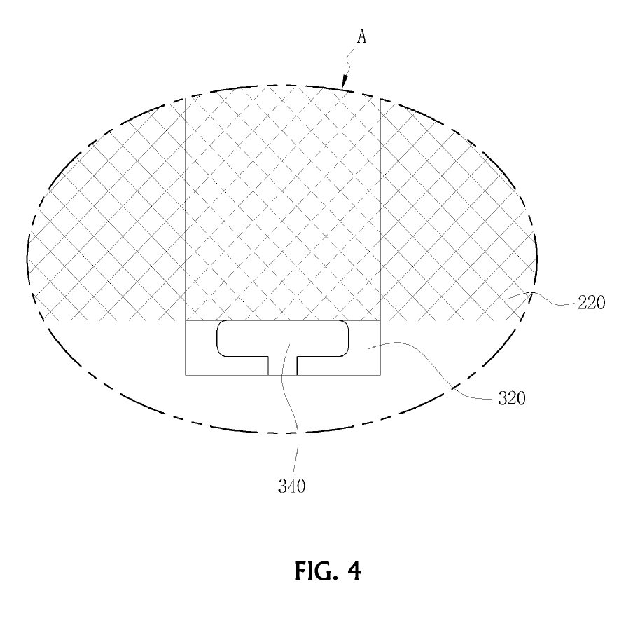

FIG. 4 is an enlarged view of the portion A in the touch panel of FIG. 3.

With reference to FIG. 4, the first pattern electrode 220 is provided in the form of a mesh of thin wires, and the first pattern electrode 220 may be configured such that the thin wires which are present in the area which overlaps with the second pattern electrode 320 are disconnected.

That is, the first pattern electrode 220 and the second pattern electrode 320 may be disposed so that there is no overlapping portion therebetween. If not so, the electrical signal may be disturbed upon external physical contact, undesirably increasing defective rates of the touch panel.

More specifically, the first pattern electrode 220 of the metal pattern unit 200 may be configured such that the thin wires which are present in the area where the first pattern electrode 220 and the second pattern electrode 320 overlap with each other may be disconnected, depending on the shape of the second pattern electrode 320 of the film substrate 300 (FIG. 2).

Consequently, when the touch panel according to the embodiment of the present invention is viewed from the front (FIGS. 3 and 4), it can be seen that the thin wires which are present in the area where the first pattern electrode 220 overlaps with the second pattern electrode 320 are disconnected.

That is, because there is no electrically overlapping area between the first pattern electrode 220 and the second pattern electrode 320, a disturbance of the electrical signal as mentioned above does not take place.

As illustrated in FIGS. 2, 3 and 4, the first pattern electrode 220 and the second pattern electrode 320 are configured such that the second pattern electrode 320 is provided in a rectangular shape, and the first pattern electrode 220 is provided in the form of the area which overlaps with the second pattern electrode 320 being disconnected, but the present invention is not limited thereto.

The second pattern electrode 320 may be provided in various shapes, such as a lozenge shape, a square shape, a rectangular shape, a circular shape, or an unstructured shape (e.g. a shape in which branches are entangled, such as dendrite).

The first pattern electrode 220 is merely disposed so that the thin wires are disconnected in the area which overlaps with the second pattern electrode 320. Specifically, the first pattern electrode 220 and the second pattern electrode 320 may be provided in a variety of shapes on the assumption that there is no electrically overlapping area therebetween.

In addition, a plurality of first pattern electrodes 220 and a plurality of second pattern electrodes 320 may be formed or combined on the transparent substrate 100.

In this case, the pattern electrodes 220, 320 may be connected to the wiring electrodes 240, 340, respectively, or the pattern electrodes 220, 320 may be connected to each other and only some of the pattern electrodes 220, 320 may be connected to the wiring electrodes.

The first pattern electrode 220 may have a wire width of 1˜10 μm. If the wire width is less than 1 μm, defective rates of a touch panel may increase. In contrast, if the wire width is greater than 10 μm, it is difficult to anticipate an increase in transparency of a touch panel.

Also, the first pattern electrode 220 may have a spacing of 200 μm or more between wires.

If the spacing between wires is less than 200 μm, transmittance of a touch panel may decrease.

Below is a description of a method of manufacturing the touch panel according to an embodiment of the present invention.

Specifically, any one surface of a transparent substrate 100 is coated with a metal thin film using a sputter system, an E-beam system or a thermal system. As such, to omit this procedure, a transparent substrate having a metal thin film may be used.

Subsequently, at least one first pattern electrode 220 in the form of a mesh of thin wires and a first wiring electrode 240 which is connected to the first pattern electrode 220 are simultaneously formed on the metal thin film positioned on the transparent substrate 100 using a wet process such as PR (Photoresist) coating, etc.

When the first pattern electrode 220 and the first wiring electrode 240 are simultaneously formed in this way, it is possible to manufacture a touch panel even without the use of an additional process, thereby simplifying the manufacturing process.

For example, the first pattern electrode 220 is provided in the form of a mesh of thin wires, and the first wiring electrode 240 is provided in a typical strip shape.

Subsequently, a second pattern electrode 320 is formed on a film substrate 300, and a second wiring electrode 320 which is connected to the second pattern electrode 320 is formed.

Specifically, the second pattern electrode 320 is formed on the film substrate 300 using a wet process such as PR (Photoresist) coating, etc. Furthermore, the second wiring electrode 320 is formed at an edge of the film substrate 300 using an Ag paste so as to be connected to the second pattern electrode 320.

Subsequently, the transparent substrate 100 and the film substrate 300 are combined with each other by means of OCA (Optical Clear Adhesive).

Subsequently, ends of the wiring electrodes 240, 340 are connected to a controller or a flexible printed circuit board (FPCB), thereby manufacturing a touch panel.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A touch panel, comprising:
a transparent substrate (100);
a metal pattern unit (200) formed under the transparent substrate (100), and including at least one first pattern electrode (220) and a first wiring electrode (240) which is connected to the first pattern electrode (220); and
a film substrate (300) combined with the transparent substrate(100) having the metal pattern unit (200), and including at least one second pattern electrode (320) and a second wiring electrode (340) which is connected to the second pattern electrode (320),
wherein the first pattern electrode (220) is in a form of a mesh of thin wires.

2. The touch panel of claim 1, wherein the metal pattern unit (200) is formed using any one selected from among Ag, Al, Cu, Cr and Ni, or an alloy thereof.

3. The touch panel of claim 1, wherein the film substrate (300) comprises ITO (Indium Tin Oxide) or a conductive polymer.

4. The touch panel of claim 1, wherein the transparent substrate (100) is a glass substrate, a transparent silicon substrate or a transparent plastic substrate.

5. The touch panel of claim 1, wherein the first pattern electrode (220) is configured such that the thin wires which are present in an area where the first pattern electrode (220) and the second pattern electrode (320) overlap with each other are disconnected.

6. The touch panel of claim 1, wherein the first pattern electrode (220) is in the form of a mesh of thin wires having a wire width of 1˜10 μm.

7. The touch panel of claim 6, wherein the first pattern electrode (220) is in the form of a mesh of thin wires having a spacing of 200 an or more between the wires.

8. A method of manufacturing a touch panel, comprising:
coating any one surface of a transparent substrate with a metal thin film;
simultaneously forming at least one first pattern electrode in a form of a mesh of thin wires and a first wiring electrode connected to the first pattern electrode on the metal thin film positioned on the transparent substrate;
forming a second pattern electrode on a film substrate, and forming a second wiring electrode which is connected to the second pattern electrode; and
combining the transparent substrate and the film substrate.
